(19) United States
(12) Patent Application Publication
(10) Pub. No.: US 2016/0111531 A1
(43) Pub. Date: Apr. 21, 2016

(54) Semiconductor Devices Including Channel Regions with Varying Widths

(71) Applicant: Samsung Electronics Co., Ltd., Suwon-si (KR)

(72) Inventor: Yaoqi Dong, Suwon-si (KR)

(21) Appl. No.: 14/723,137

(22) Filed: May 27, 2015

(30) Foreign Application Priority Data
Oct. 16, 2014 (KR) 10-2014-0140164

(51) Int. Cl. H01L 29/78; H01L 29/10; H01L 29/06; H01L 29/423; H01L 29/417

(52) U.S. Cl. CPC H01L 29/785; H01L 29/7851; H01L 29/42376; H01L 29/4238; H01L 29/41791; H01L 29/0653; H01L 29/1033

(57) ABSTRACT

A semiconductor device includes a semiconductor substrate, a fin-type structure on the semiconductor substrate, and a gate on a portion of a top surface and portions of two side surfaces of the fin-type structure. The gate has a first width at a first level from the top surface of the substrate and a second width at a second level from the top surface of the substrate that is lower than the first level. The first width is greater than the second width, and a width of the gate is reduced from the first width to the second width between the first level and the second level.

### CROSS-REFERENCE TO RELATED APPLICATION

This application claims the benefit of Korean Patent Application No. 10-2014-0140164, filed on Oct. 16, 2014, in the Korean Intellectual Property Office, the disclosure of which is incorporated herein in its entirety by reference.

### BACKGROUND

The inventive concept relates to a semiconductor device including a transistor, and more particularly, to a semiconductor device including a fin-type field-effect transistor (FinFET).

With the increasing integration density of semiconductor devices, design rules of elements of the semiconductor devices have been reduced. When older transistor designs, such as planar-type metal-oxide-semiconductor field-effect transistors (MOSFETs) are reduced in size, their channel regions are also reduced in size, which undesirably limits the operation of the devices.

To enable increased integration, density, the fin-type FET (FinFET) structure, which includes a three-dimensional (3D) fin-type channel region, has been developed to ensure a sufficient channel region.

### SUMMARY

The inventive concept provides a semiconductor device including a fin-type field-effect transistor (FinFET), which may have an increased channel current density. Increasing the channel current density of a transistor device may help to enable high-speed operation of the device and/or may reduce power consumption of the semiconductor device.

According to an aspect of the inventive concept, there is provided a semiconductor device including a semiconductor substrate, a fin-type structure feted on the semiconductor substrate, an insulating layer formed on the semiconductor substrate to have a top surface that is at a lower level than a top surface of the fin-type structure, and a gate covering a portion of a top surface and portions of two side surfaces of the fin-type structure. The gate covering the portions of the two side surfaces of the fin-type structure has a first width at a first level from the top surface of the insulating layer and a second width at a second level lower than the first level. The first width is greater than the second width. A width of the gate is reduced from the first width to the second width between the first level and the second level.

The width of the gate may be reduced at a constant rate of change from the first width to the second width between the first level and the second level.

The width of the gate may be reduced at at least two rate of changes from the first width to the second width between the first level and the second level.

The width of the gate may be reduced at a continuously varying rate of change from the first width to the second width between the first level and the second level.

The first level may be at substantially the same level as a top surface of the gate.

The first level may be at a lower level than a top surface of the gate.

The second level may be at substantially the same level as the top surface of the insulating layer.

The second level may be at an upper level than the top surface of the insulating layer.

A third width obtained at a third level that is lower than the second level may be equal to or larger than the second width.

A distance from the top surface of the gate to the second level may be greater than a distance front the second level to the third level.

A third width obtained at a third level that is lower than the first level may be equal to or smaller than the first width.

A distance from the top surface of the insulating layer to the first level may be greater than a distance from the first level to the third level.

A source region and a drain region may be formed on the fin-type structure on two sides of the gate. A first resistance between the source region and the drain region on the two sides of the gate at the first level may be greater than a second resistance between the source region and the drain region on the two sides of the gate at the second level.

The fin-type structure may protrude from the substrate, and the insulating layer may define the fin-type structure.

The fin-type structure may be formed on the insulating layer.

A gate dielectric layer may be interposed between the fin-type structure and the gate. On the side surfaces of the fin-type structure, a source voltage and a drain voltage may be respectively applied to the source region and the drain region on both sides of the gate.

According to another aspect of the inventive concept, there is provided a semiconductor device including a semiconductor substrate, a fin-type structure formed on the semiconductor substrate, an insulating layer formed on the semiconductor substrate to have a top surface that is at a lower level than a to surface of the fin-type structure, and a gate covering a portion of a top surface of the fin-type structure and portions of two side surface of the fin-type structure. The gate covering the portions of the side surfaces of the fin-type structure includes a range in which a width of the gate is reduced toward a lower portion of the fin-type structure.

In the range, the gate may include a first side and a second side that extend from an upper portion of the fin-type structure toward a lower portion thereof. The first side of the gate may extend in a first direction, and the second side of the gate may extend in a second direction that is inclined at a different angle from the first direction with respect to a direction vertical to the insulating layer.

According to another aspect of the inventive concept, there is provided a semiconductor device including a semiconductor substrate, a plurality of fin-type structures formed on the semiconductor substrate, an insulating layer formed on the semiconductor substrate such that a top surface of the insulating layer is at a lower level than the plurality of fin-type structures, and at least one gate configured to extend onto the insulating layer and cover a top surface and a side surface of each of the plurality of fin-type structures to intersect the plurality of fin-type structures. The at least one gate includes a block of which a width is reduced from the side surface of each of the fin-type structures toward a lower portion thereof.

A plurality of gates may be provided. At least one of the plurality of fin-type structures may intersect the plurality of gates.

### BRIEF DESCRIPTION OF THE DRAWINGS

Exemplary embodiments of the inventive concept will be more clearly understood from the following detailed description taken in conjunction with the accompanying drawings in which:

FIG. 1A is a perspective view of a semiconductor device according to exemplary embodiments of the inventive concept;

FIG. 1B is a perspective view of a channel region of the semiconductor device of FIG. 1A;

FIG. 1C is a cross-sectional view of the semiconductor device of FIG. 1A, which is taken along a line A-A′ of FIG. 1A, according to an exemplary embodiment of the inventive concept;

FIG. 1D is a cross-sectional view of the semiconductor device of FIG. 1A, which is taken along a line A-A′ of FIG. 1A, according to another exemplary embodiment of the inventive concept;

FIG. 2 is a schematic view of operations of a semiconductor device according to exemplary embodiments of the inventive concept;

FIG. 3A is a graph of a channel current relative to the width of a gate in an on state;

FIG. 3B is a graph of a channel current relative to the width of a gate in an off state;

FIGS. 4A to 9B are perspective views and front views of a semiconductor device according to exemplary embodiments of the inventive concept, wherein FIGS. 4B, 5B, 6B, 7B, 8B, and 9B are respectively sectional views taken along a line B-B′ of FIG. 4A, a line C-C′ of FIG. 5A, a line D-D′ of FIG. 6A, a line E-E′ of FIG. 7A, a line F-F′ of FIG. 8A, and a line G-G′ of FIG. 9A;

FIGS. 10 and 11 are perspective views of a semiconductor device according to exemplary embodiments of the inventive concept;

FIGS. 12A to 12G are cross-sectional views illustrating a method of fabricating a semiconductor device according to exemplary embodiments of the inventive concept;

FIG. 13 is a diagram of a system including a semiconductor device according to an exemplary embodiment of the inventive concept; and

FIG. 14 is a diagram of a memory card including a semiconductor device according to an exemplary embodiment of the inventive concept.

### DETAILED DESCRIPTION OF THE EMBODIMENTS

The inventive concept is described more fully hereinafter with reference to the accompanying drawings, in which embodiments of the inventive concept are shown. This inventive concept may, however, be embodied in many different forms and should not be construed as limited to the embodiments set forth herein. Rather, these embodiments are provided so that this disclosure will be thorough and complete, and will fully convey the scope of the inventive concept to those skilled in the art. Like reference numerals in the drawings denote like elements, and thus their description will be omitted.

It will be understood that, although the terms first, second, etc. may be used herein to describe various elements, components, regions, layers and/or sections, these elements, components, regions, layers and/or sections should not be limited by these terms. Thus, a first element, component, region, layer or section discussed below could be termed a second element, component, region, layer or section without departing from the teachings of the inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and this specification and will not be interpreted in an idealized or overly formal sense unless explicitly so defined herein.

Unless explicitly defined in a specific order herein, respective steps described in the inventive concept may be performed otherwise. That is, the respective steps may be performed in a specified order, substantially at the same time, or in reverse order.

Variations from the shapes of the illustrations as a result, for example, of manufacturing techniques and/or tolerances, are to be expected. Thus, embodiments of the inventive concept should not be construed as limited to the particular shapes of regions illustrated herein but are to include deviations in shapes that result, for example, from manufacturing.

As used herein, the term “and/or” includes any and all combinations of one or more of the associated listed items. Expressions such as “at least one of” when preceding a list of elements, modify the entire list of elements and do not modify the individual elements of the list.

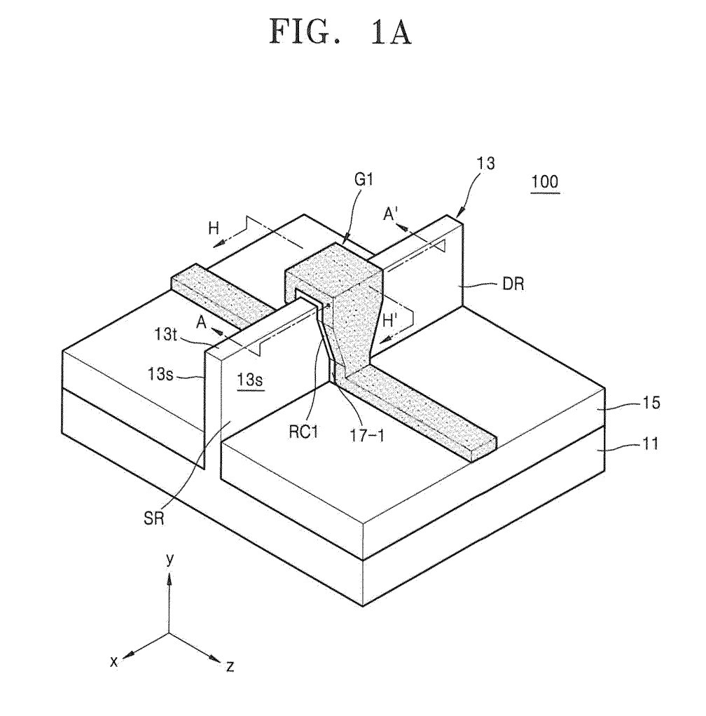

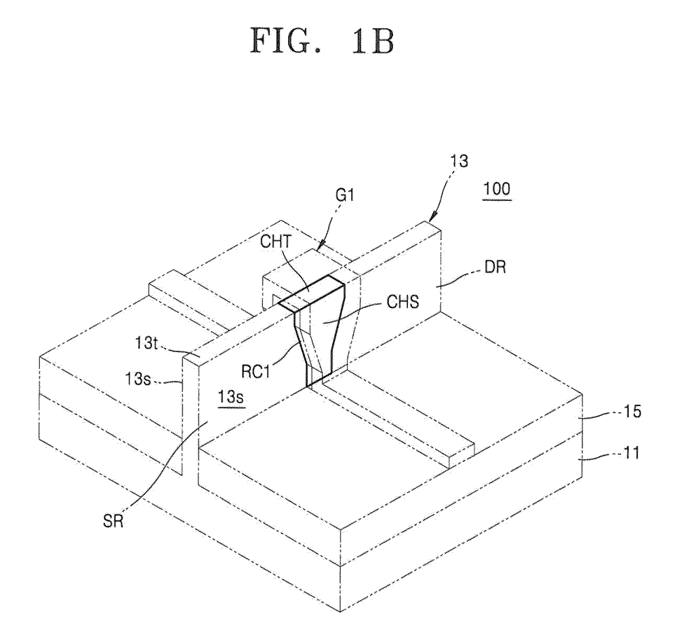

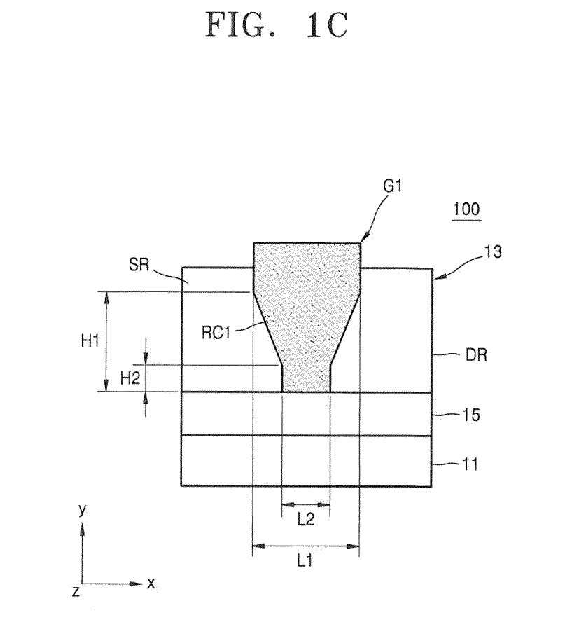

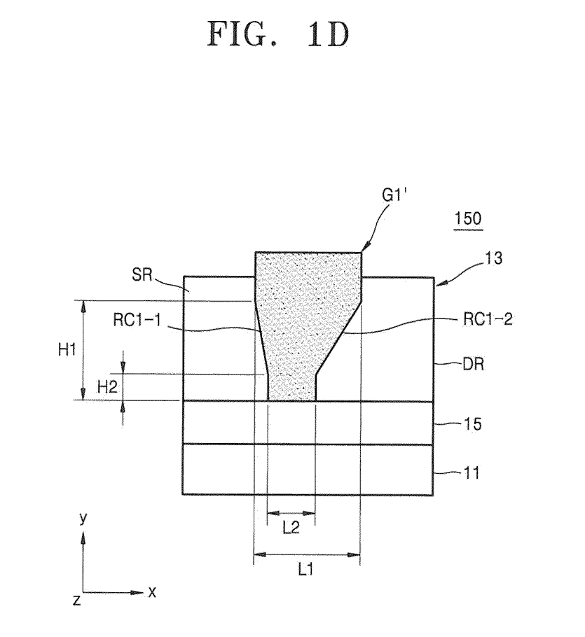

FIG. 1A is a perspective view of a semiconductor device 100 according to exemplary embodiments of the inventive concept.

Referring to FIG. 1A, the semiconductor device 100 may include a fin-type structure 13 that may protrude from a semiconductor substrate 11. The fin-type structure 13 may be defined by an insulating layer 15 that may have a top surface that is at a lower level than a top surface of the fin-type structure 13 and be formed on the semiconductor substrate 11. The semiconductor device 100 may include a gate G1, which may extends across portions of two side surfaces 13s and a portion of a top surface 13t of the fin-type structure 13 across the fin-type structure 13. The top surface 13t of the fin-type structure 13 is the surface of the fin-type structure opposite the underlying substrate 11. On the side surfaces of the tin-type structure 13, a width of the gate G1 may be reduced from an upper portion of the gate G1 toward a lower portion thereof. The gate G1 having a range in which the width of the gate G1 is reduced from the upper portion of the gate G1 toward the lower portion thereof may increase a channel current density, thereby enabling rapid operations of the semiconductor device 100 and reducing power consumption of the semiconductor device 100. In this context, “upper portion” refers to a portion of the fin or gate that is distal (far) from the underlying substrate, while “lower portion” refers to a portion of the fin or gate that is proximate (near) the underlying substrate.

The semiconductor substrate 11 may include silicon (Si), for example, crystalline silicon, polycrystalline silicon (poly-Si), or amorphous silicon (a-Si). In some other embodiments, the semiconductor substrate 11 may include germanium (Ge) or a compound semiconductor, such as silicon germanium (SiGe), silicon carbide (SiC), gallium arsenide (GaAs), indium arsenide (InAs), or indium phosphide (InP). In at least one embodiment, the semiconductor substrate 11 may be disposed on an insulator such as a silicon-on-insulator (SOD or a thin-film transistor (TFT). The semiconductor substrate 11 may include a doped epitaxial layer or a buried layer. In another example, a compound semiconductor substrate may have a multilayered structure. In some embodiments, the semiconductor substrate 11 may include a conductive region, for example, a doped well or a doped structure.

The fin-type structure 13 may protrude as a fin type from a top surface of the insulating layer 15, and extend in one direction (refer to x direction in FIG. 1A). The semiconductor device 100 may operate by applying a voltage to the gate G1 disposed across the fin-type structure 13 and a source region SR and a drain region DR formed on two sides of the gate G1. Since the fin-type structure 13 protrudes from the semiconductor substrate 11, the fin-type structure 13 may include the same material as the semiconductor substrate 11. In some embodiments, the fin-type structure 13 may further include impurities, for example, arsenic (As), phosphorus (P), other Group V elements, or a combination thereof, or boron (B), aluminium (Al) other Group III elements, or a combination thereof.

Although FIG. 1A illustrates a case in which the fin-type structure 13 protrudes from the substrate 11, the inventive concept is not limited thereto. In some embodiments, the fin-type structure 13 may be formed on the insulating layer 15 formed on the semiconductor substrate 11. In this case, the fin-type structure 13 may be formed using an epitaxial growth process.

FIG. 1A illustrates a case in which a cross-section of the fin-type structure 13, which is taken in a direction perpendicular to a direction in which the fin-type structure 13 extends, has a square shape, but the inventive concept is not limited thereto. Each of the two side surfaces of the fin-type structure 13 may have a polygonal shape, such as a parallelogram shape or a pentagonal shape.

The insulating layer 15 may electrically insulate the fin-type structure 13 from other elements disposed on the semiconductor substrate 11. In some embodiments, the insulating layer 15 may include an oxide layer, a nitride layer, a carbide layer, a polymer, or a combination thereof, but is not limited thereto.

A gate dielectric layer 17-1 may be formed between the gate G1 and the fin-type structure 13 to cover the top surface and two side surfaces of the fin-type structure 13, and the gate G1 may extend to cover the top surface and two side surfaces of the fin-type structure 13 and a top surface of the insulating layer 15. The gate G1 may extend in a direction (refer to z direction in FIG. 1A) that may intersect the fin-type structure 13. The gate G1 may have a range in which the width of the gate G1 is reduced toward the lower portion of the fin-type structure 13 on each of the side surfaces of the fin-type structure 13. The width of the gate G1 in the range may be reduced at a constant rate of change RC1. That is, the width of the gate G1 may change in a linear fashion from an upper portion of the fin to a lower portion of the fin. The range in which the width of the gate G1 is reduced may range from an uppermost portion of the gate G1 to a lowermost portion thereof or a partial range selected out of the whole range from the uppermost portion of the gate G1 to the lowermost portion thereof. Detailed descriptions will be presented below with reference to FIG. 1C.

The gate G1 may include a conductive material. In some embodiments, the gate G1 may include poly-Si, SiGe, and metals including metal compounds, such as aluminum (Al), molybdenum (Mo), copper (Cu), tungsten (W), titanium (Ti), tantalum (Ta), titanium nitride (TiN), tantalum nitride (TaN), nickel suicide (NiSi), and cobalt suicide (CoSi), and a combination thereof. In other embodiments, the gate G1 may include a poly-Si layer formed on a metal layer.

The gate dielectric layer 17-1 may be a single layer or a multilayered structure. The gate dielectric layer 17-1 may include a high-k layer having a higher dielectric constant than a silicon oxide layer. For example, the gate dielectric layer 17-1 may have a dielectric constant of about 10 to about 25. In some embodiments, the gate dielectric layer 17-1 may include at least one material selected from the group consisting of hafnium oxide (HfO), hafnium silicon oxide (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicon oxide (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), or lead scandium tantalum oxide (PbScTaO). In some embodiments, the gate dielectric layer 17-1 may be formed using an atomic layer deposition (ALD) process.

FIG. 1B is a perspective view of a channel region of the semiconductor device 100 of FIG. 1A. The same reference numerals are used to denote the same elements and thus, repeated descriptions thereof are omitted.

Referring to FIG. 1B, the gate G1 may extend across the top surface 13t and two side surfaces 13s of the fin-type structure 13 and the top surface of the insulating layer 15. Thus, in the semiconductor device 100, a top channel region CHT and side channel regions CHS may be formed on the top surface and two side surfaces of the fin-type structure 13. The semiconductor device 10 having a three-dimensional (3D) structure may have a considerably high channel current density as compared with a planar-type metal-oxide-semiconductor field-effect transistor (MOSFET) device having one surface on which a channel region is formed.

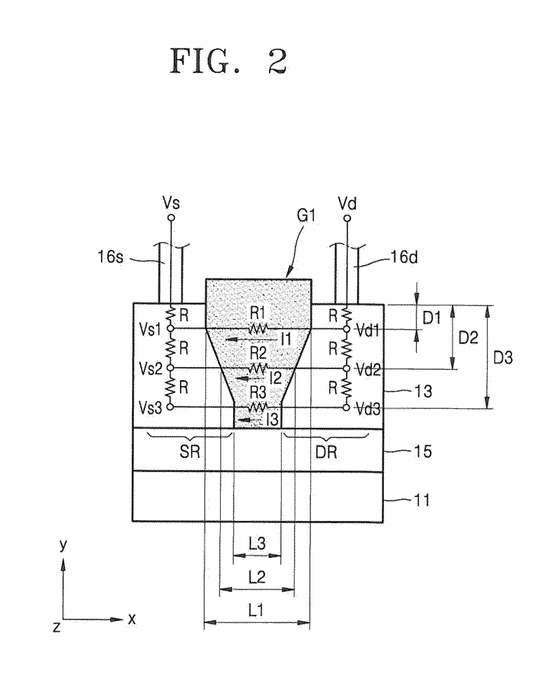

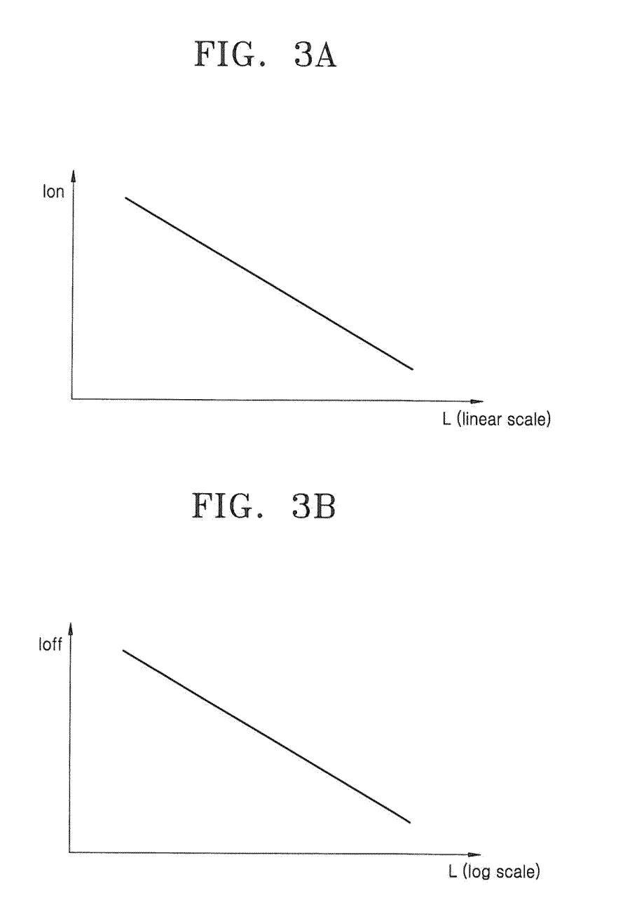

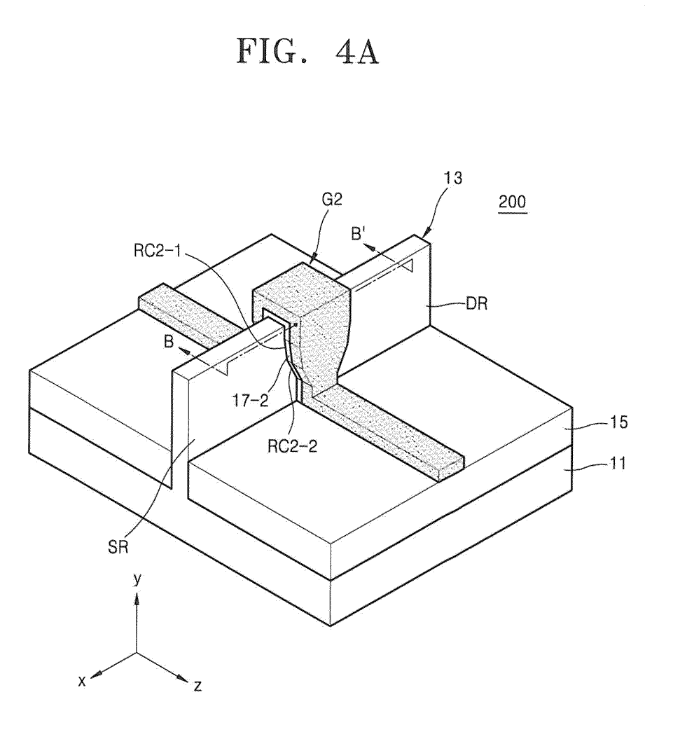

However, even if the channel regions CHT and CHS are widened, an increase in channel current density may be precluded because a source-drain voltage difference is reduced from an upper portion of the fin-type structure 13 toward a lower portion thereof. However, according to the inventive concept, the gate G1 may include a range in which the width of the gate G1 is reduced from the upper portion of the fin-type structure 13 toward the lower portion thereof to solve a problem in which the source-drain voltage difference is reduced from the upper portion of the fin-type structure 13 to the lower portion thereof. Thus, even if the source-drain voltage difference is reduced, a sufficient channel current may be ensured as described in detail later with reference to FIGS. 2, 3A, and 3B.

FIG. 1C is a cross-sectional view of the semiconductor device 100 of FIG. 1A, which is taken along a line A-A′ of FIG. 1A. The same reference numerals are used to denote the same elements and thus, repeated descriptions thereof are omitted. Reference numerals H1, H2, H3, L1, L2, and L3 denote relative heights or widths in each of drawings and may differ among the drawings.

Referring to FIG. 1C, an insulating layer 15 may be formed on the semiconductor substrate 11, and a gate G1 may cover a portion of the fin-type structure 13 that protrudes upward from the insulating layer 15. In the fin-type structure 13, the gate G1 may have a first width L1 at a first level H1 from a top surface of the insulating layer 15, and have a second width L2 at a second level H2 that is lower than the first level H1. A width of the gate G1 may be gradually reduced from the first width L1 obtained at the first level H1 to the second width L2 obtained at the second level H2. In this case, the width of the gate G1 may be reduced from the first width L1 to the second width L2 at a constant rate of change RC1. It will be appreciated that the width of the gate G1 may vary according to other profiles or rates of change. For example, the width of the gate G1 may change from an upper portion of the fin to a lower portion of the fin in a stepped fashion, a parabolic fashion, a quasi-linear fashion, a piecewise linear fashion, or other fashion, as will be described and illustrated below.

FIG. 1D is a cross-sectional view of the semiconductor device 100 of FIG. 1A, which is taken along the line A-A′ of FIG. 1A, according to another exemplary embodiment of the inventive concept. A semiconductor device 150 may be similar to the semiconductor device 100 shown in FIGS. 1A to 1C except for rate of changes of two corners of a gate G1′.

Referring to FIG. 1D, a width of the gate G1′ of the semiconductor device 150 may be reduced from a first width L1 obtained at a first level H1 to a second width L2 obtained at a second level H2 at constant rate of changes, namely, first and second rate of changes RC1-1 and RC1-2.

However, when the gate G1′ is vertically bisected and examined, it can be seen that a width of a portion of the gate G1′, which includes a left corner of the gate G1′, may have the first rate of change RC1-1, while a width of a portion of the gate G1′, which includes a right corner of the gate G1′, may have the second rate of change RC1-2 that is a sharper change than the first rate of change RC1-1. That is, the gate G1′ may have a first side and a second side, which may extend from the upper portion of the fin-type structure 13 toward the lower portion thereof, the first side may extend in a first direction, and the second side may extend in a second direction that is inclined at a different angle from the first direction with respect to a direction vertical to the insulating layer 15.

As described above, a structure that tapers from an upper portion of the gate G1′ toward a lower portion thereof may be variously selected according to purposes.

FIG. 2 is a schematic view of operations of a semiconductor device 100 according to exemplary embodiments of the inventive concept.

In the semiconductor device 100 including a fin-type structure 13, a channel current may be generated in a top surface 13t and two side surfaces 13s of the fin-type structure 13 between a source region SR and a drain region DR. Thus, the semiconductor device 100 may have a considerably high channel current density as compared with a planar-type MOSFET device having one surface by which a channel current is generated. However, since the source region SR and the drain region DR also expand to the whole range of the fin-type structure 13, a voltage drop may occur due to a resistance R of the fin-type structure 13, Source voltages Vs, Vs1, Vs2, and Vs3 and drain voltages Vd, Vd1, Vd2, and Vd3 may vary based on position in the source region SR and the drain region DR.

Specifically, a drain voltage Vd may be applied to a top surface of the drain region DR of the fin-type structure 13 through a contact unit 16d. However, since a series resistance R occurs due to the fin-type structure 13 itself, an effective drain voltage Vd within the fin may drop due to the resistance R from an upper portion of the drain region DR to a lower portion thereof. Assuming that a voltage obtained in a first distance D1 in a vertical downward direction from the top surface of the drain region DR is a first drain voltage Vd1, the first drain voltage Vd1 may drop due to the resistance R and become lower than the applied drain voltage Vd. Similarly, assuming that a voltage obtained in a second distance D2 in a vertical downward direction from the top surface of the drain region DR is a second drain voltage Vd2, the second drain voltage Vd2 may be lower than the first drain voltage Vd1. Assuming that a voltage obtained in a third direction D3 in a vertical downward direction from the top surface of the drain region DR is a third drain voltage Vd3, the third drain voltage Vd3 may be lower than the second drain voltage Vd2.

Like in the drain region DR, a similar voltage drop may occur in the source region SR. Specifically, since a series resistance R occurs due to the fin-type structure 13, a voltage drop may occur also in the source region SR. A source voltage Vs may be applied to a top surface of the source region SR through a contact unit 16s. In this ease, the source voltage Vs may be lower than the drain voltage Vd. The source voltage Vs may be a ground voltage. In this case, assuming that a voltage obtained in the third distance D3 in a vertical downward direction from the top surface of the source region SR is a third source voltage Vs3, a second source voltage Vs2 obtained in the second distance D2 in the vertical downward direction from the top surface of the source region SR may drop due to the resistance R and become lower than the third source voltage Vs3. Furthermore, assuming that a voltage obtained in the first distance D1 in the vertical downward direction from the top surface of the source region SR is a first source voltage Vs1, the first source voltage Vs1 may be lower than the second source voltage Vs2.

Thus, a first source-drain voltage difference Vds1 obtained in the first distance D1, a second source-drain voltage difference Vds2 obtained in the second distance D2, and a third source-drain voltage difference Vds3 obtained in the third distance D3 may be sequentially reduced.

In a FinFET device in which a gate has a constant width (in contrast to embodiments of the inventive concept described herein), since the gate has the constant width, a first source-drain voltage difference Vds1, a second source-drain voltage difference Vds2, and a third source-drain voltage difference Vds3, which are respectively different, may be applied with respect to the same channel resistance. Thus, second and third channel currents generated in the second distance D2 and the third distance D3 may be much smaller than a first channel current generated in a first distance D1. Although a reduction in channel leakage current in an off state does not affect operations of a device, a reduction in channel current in an on state may deteriorate the operations of the device.

In a semiconductor device 100 according to the inventive concept, the width of the gate G1 may be reduced from an upper portion of the gate G1 toward a lower portion thereof. For example, a width L1 of the gate G1 in the first distance D1, a width L2 of the gate G1 in the second distance D2, and a width L3 of the gate G1 in the third distance D3 may be sequentially reduced. Thus, a resistance R1 obtained in the first distance D1, a resistance R2 obtained in the second distance D2, and a resistance R3 obtained in the third distance D3, which may affect a channel current, may be sequentially reduced. Accordingly, even if the first source-drain voltage difference Vds1, the second source-drain voltage difference Vds2, and the third source-drain voltage difference Vds3 are sequentially reduced, respective resistances corresponding to the source-drain voltage difference Vds1, the second source-drain voltage difference Vds2, and the third source-drain voltage difference Vds3 may also be reduced. As a result, not only a first channel current I1 obtained in the first distance D1, but also a second channel current I2 obtained in the second distance D2, and a third channel current I3 obtained in the third distance D3 may be sufficiently ensured.

As is well known in the art, the channel current may be expressed as Ich=(Vds/Rch), where Ich is the channel current, Vds is the drain to source voltage, and Rch is the channel resistance. As noted above, the value of Vds decreases from the upper portion of the fin to the lower portion of the fin. In accordance with some embodiments, the channel resistance Rch is varied from the upper portion of the fin to the lower portion of the fin so that the ratio of Vds to Rch, which equals the channel current Ich, stays relatively constant from the upper portion of the fin to the lower portion of the fin.

FIG. 3A is a graph of a channel current relative to the width of a gate in an on state, and FIG. 3B is a graph of a channel current relative to the width of a gate in an off state.

Referring to FIG. 3A, when a semiconductor device is in an on state, as a width of a gate increases, a channel current may tend to linearly decrease.

Referring to FIG. 3B, as in the on state, when the semiconductor device is in the off state, as the width of the gate increases, a channel current may tend to decrease. However, in FIG. 3B, the width of the gate is graphed on a log scale. Thus, a variation in channel leakage current relative to a variation in the width of the gate may not be big in the off state.

Accordingly, when the width of the gate is increased or decreased, a channel current in the on state may be relatively largely affected by the adjusted width of the gate, while a channel leakage current in the off state may be relatively slightly affected by the adjusted width of the gate.

Thus, referring again to FIGS. 2, 3A, and 3B, even if the first source-drain voltage difference Vds1, the second source-drain voltage difference Vds2, and the third source-drain voltage difference Vds3 are sequentially reduced, a width L1 of the gate obtained in a first distance D1, a width L1.5 of the gate obtained in a second distance D2, and a width L2 of the gate obtained in a third distance D3 may be sequentially reduced, so that respective resistances corresponding to the source-drain voltage difference Vds1, the second source-drain voltage difference Vds2, and the third source-drain voltage difference Vds3 may be reduced. Therefore, both the channel leakage current in the off state and the channel current in the on state may be increased. However, as compared with the off state in which the channel leakage current increases at an extremely slight rate, the channel current that may linearly increase in proportion to a reduction in width in the on state may increase an operating speed of the semiconductor device and reduce power consumption of the semiconductor device. Also, as the width of the gate G1 is reduced, an area by which the gate G1 faces a side channel region CHS may also be reduced so that a capacitance between the gate G1 and the side channel region CHS may be reduced. A reduction in the capacitance between the gate G1 and the side channel region CHS may lead to an increase in the operating speed of the semiconductor device and a reduction in the power consumption of the semiconductor device.

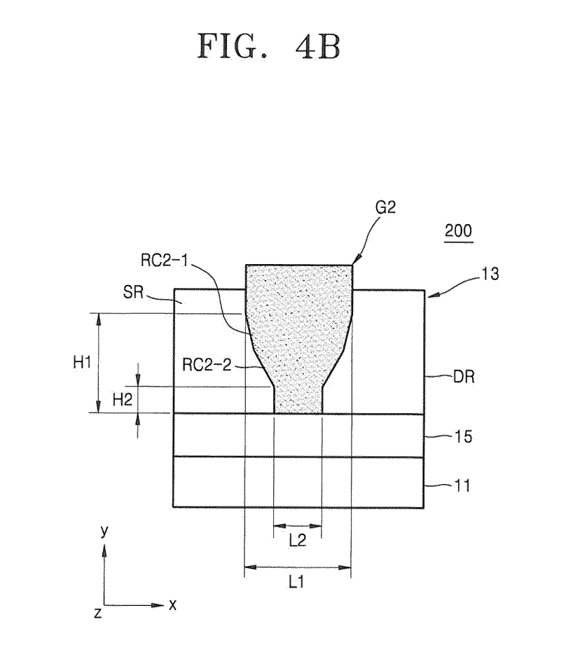

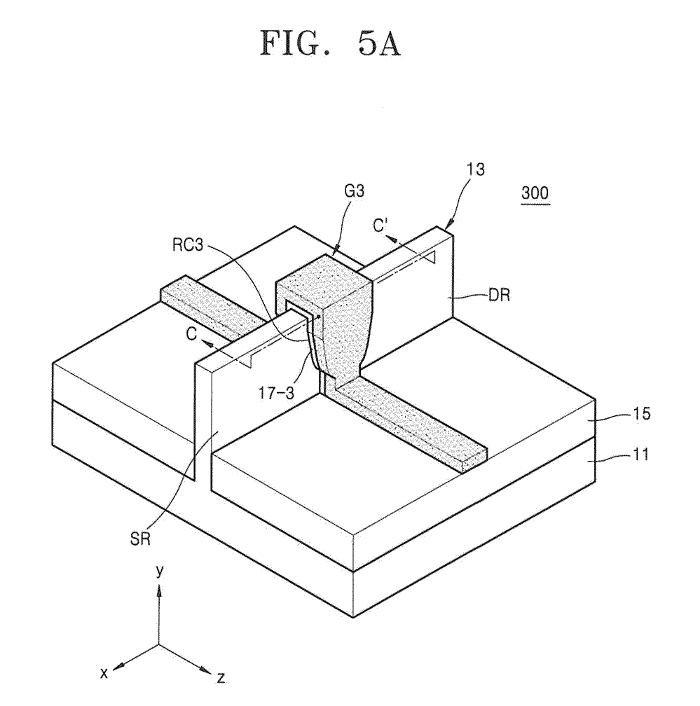

FIGS. 4A and 4B are respectively a perspective view and a front view of a semiconductor device 200 according to exemplary embodiments of the inventive concept. The semiconductor device 200 is similar to the semiconductor device 100 shown in FIGS. 1A to 1C except for an aspect of a reduction in width of a gate G2. In FIGS. 4A and 4B, the width of the gate G3 varies in a piecewise linear fashion.

Referring to FIGS. 4A and 4B, the width of the gate G2 may be reduced at two rate of changes from a first width L1 to a second width L2 between a first level H1 and a second level H2. There may be a third level H3 between the first level H1 and the second level H2. The width of the gate G2 may be reduced at a first rate of change RC2-1 from the first level H1 to the third level H3, and reduced at a second rate of change RC2-2 from the third level H3 to the second level H2. Although FIGS. 4A and 4B illustrate an example in which the first rate of change RC2-1 is higher than the second rate of change RC2-2, the inventive concept is not limited thereto, and the first rate of change RC2-1 may be lower the second rate of change RC2-2. In some embodiments, the width of the gate G2 may be changed at at least three rate of changes between the first level H1 and the second level H2.

Referring to FIG. 4A, a gate dielectric layer 17-2 interposed between the gate G2 and the fin-type structure 13 may have a similar shape to the gate G2.

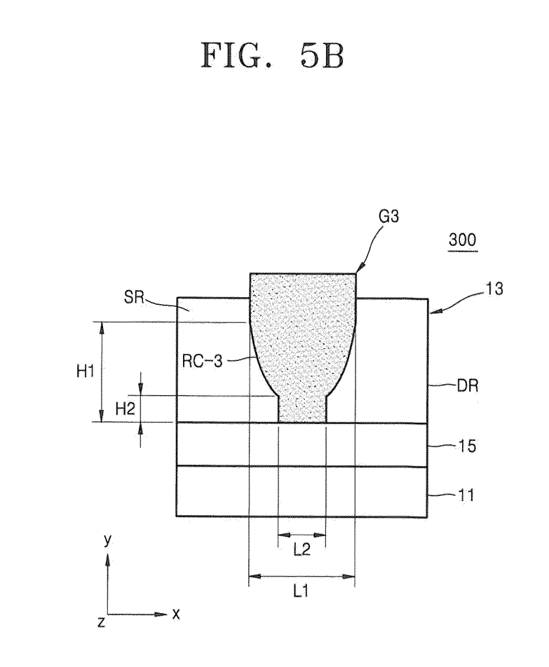

FIGS. 5A and 5B are respectively a perspective view and a front view of a semiconductor device 300 according to exemplary embodiments of the inventive concept. The semiconductor device 300 is similar to the semiconductor device 100 shown in FIGS. 1A to 1C except for an aspect of a reduction in width of a gate G3. In FIGS. 5A and 5B, the width of the gate G3 varies in a parabolic fashion.

Referring to FIGS. 5A and 5B, the width of the gate G3 may be reduced at a continuously varying rate of change RC3 from a first width L1 to a second width L2 between a first level H1 and a second level H2. Referring to FIG. 5A, a gate dielectric layer 17-3 interposed between the gate G3 and the fin-type structure 13 may have a similar shape to the gate G3.

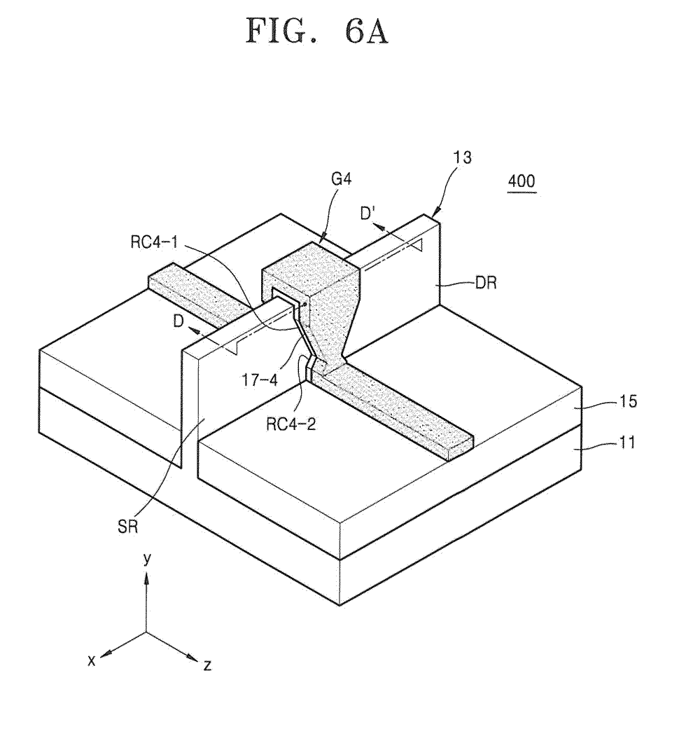

FIGS. 6A and 6B are respectively a perspective view and a front view of a semiconductor device 400 according to exemplary embodiments of the inventive concept. The semiconductor device 400 is similar to the semiconductor device 100 shown in FIGS. 1A to 1C except that a width of a gate G4 is reduced and then increased again.

Referring to FIGS. 6A and 6B, the width of the gate G4 may be reduced at a first rate of change RC4-1 from a first width L1 obtained at a first level H1 to a second width L2 obtained at a second level H2. Also, the width of the gate G4 may be increased again at an second rate of change RC4-2 from the second width L2 obtained at the second level H2 to the third width L3 obtained at the third level H3. In some embodiments, a range having the decreasing rate of change RC4-1 may be reduced at at least two rate of changes or reduced at a continuously varying rate of change.

In some embodiments, a range having the first rate of change RC4-1 may be wider than a range having the second rate of change RC4-2. Referring to FIG. 6A, a gate dielectric layer 17-4 interposed between the gate G4 and the fin-type structure 13 may have a similar shape to the gate G4.

FIGS. 1A to 1C and 4A to 6B illustrate cases in which the width of each of the gates G1, G2, G3, and G4 is changed in a predetermined range from the first level Hi to the second level H2 or the third level H3, but the inventive concept is not limited thereto.

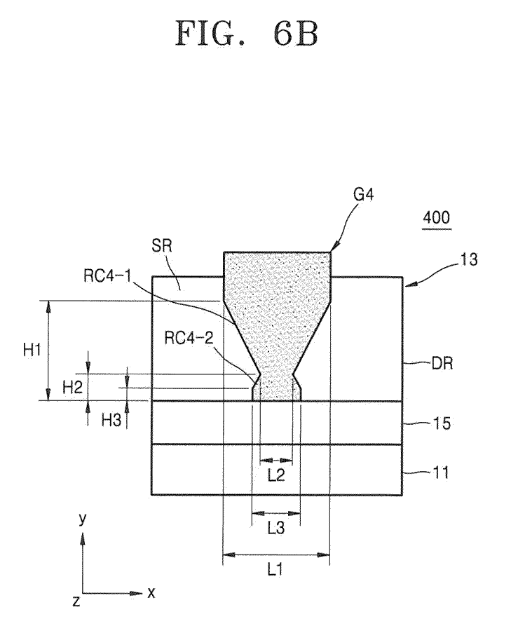

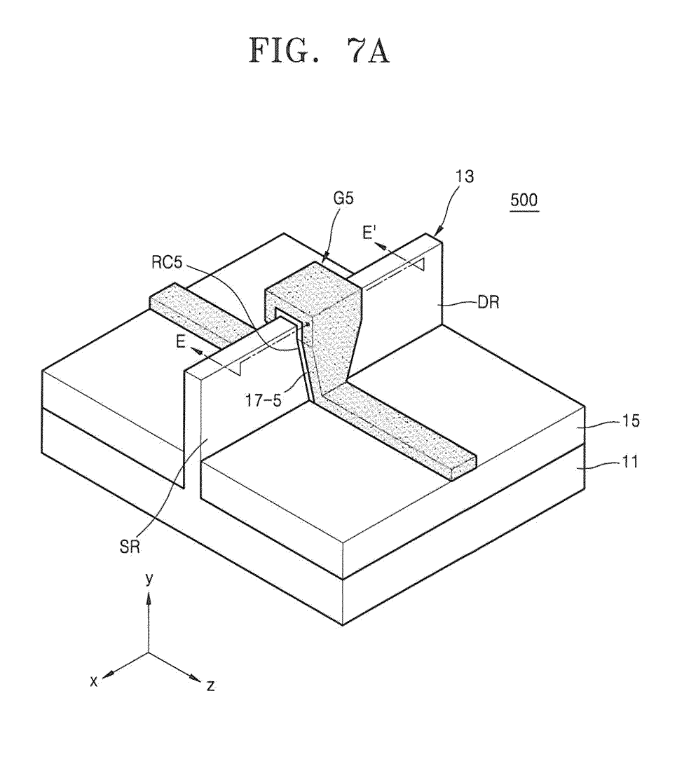

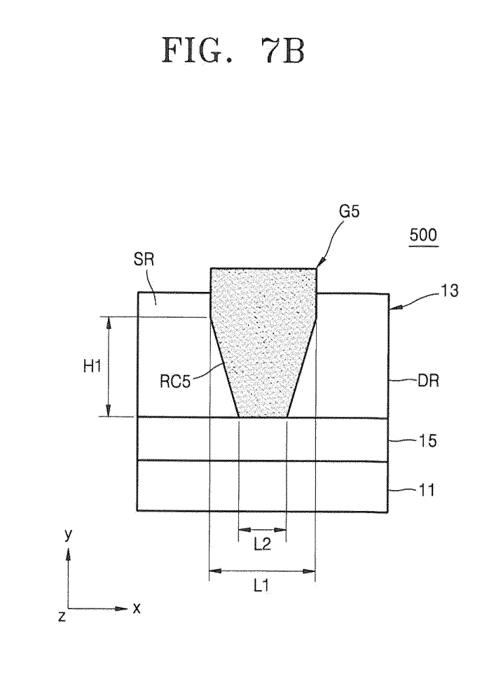

FIGS. 7A and 7B are respectively a perspective view and a front view of a semiconductor device 500 according to exemplary embodiments of the inventive concept. The semiconductor device 500 is similar to the semiconductor device 100 shown in FIGS. 1A to 1C except for a range in which a width of a gate G5 is reduced.

Referring to FIGS. 7A and 7B, the width of the gate G5 may be reduced at a constant rate of change RC5 from a first width L1, which is obtained at a first level H1 lower than a top surface of the gate G5, to a second width L2 obtained at a lower portion of the gate G5. In some embodiments, a range in which the width of the gate G5 is constant from the top surface of the gate G5 to the first level H1 may be narrower than a range in which the width of the gate G5 has the constant rate of change RC5. In some embodiments, in the range in which the width of the gate G5 has the rate of change RC5, the width of the gate G5 may be reduced at at least two rate of changes or reduced at a continuously varying rate of change. Referring to FIG. 7A, a gate dielectric layer 17-5 interposed between the gate G5 and the fin-type structure 13 may have a similar shape to the gate G5.

FIGS. 8A and 8B are respectively a perspective view and a front view of a semiconductor device 600 according to exemplary embodiments of the inventive concept. The semiconductor device 600 is similar to the semiconductor device 100 shown in FIGS. 1A to 1C except for a range in which a width of a gate G6 is reduced.

Referring to FIGS. 8A and 8B, the width of the gate G6 may be reduced constantly at a rate of change RC6 from a first width L1 obtained at a first level H1, which is at substantially the same level as a top surface of the gate G6, to a second width L2 obtained at a second level H2, which is at a higher level than a lower portion of the gate G6. In some embodiments, in a range in which the width of the gate G6 has the rate of change RC6, the width of the gate G6 may be reduced at at least two rate of changes or reduced at a continuously varying rate of change. Referring to FIG. 8A, a gate dielectric layer 17-6 interposed between the gate G6 and the fin-type structure 13 may have a similar shape to the gate G6.

FIGS. 9A and 9B are respectively a perspective view and a front view of a semiconductor device 700 according to exemplary embodiments of the inventive concept. The semiconductor device 700 is similar to the semiconductor device 100 shown in FIGS. 1A to 1C except for a range in which a width of a gate G7 is reduced.

Referring to FIGS. 9A and 9B, the width of the gate G7 may be reduced constantly at a rate of change RC7 from a first width L1 obtained at a first level H1, which is at substantially the same level as a top surface of the gate G7, to a second width L2 obtained at a second level H2, which is at substantially the same level as a lower portion of the gate G7. In some embodiments, in a range in which the width of the gate G7 has the rate of change RC7, the width of the gate G7 may be reduced at at least two rate of changes or reduced at a continuously varying rate of change. Referring to FIG. 9A, a gate dielectric layer 17-7 interposed between the gate G7 and the fin-type structure 13 may have a similar shape to the gate G7.

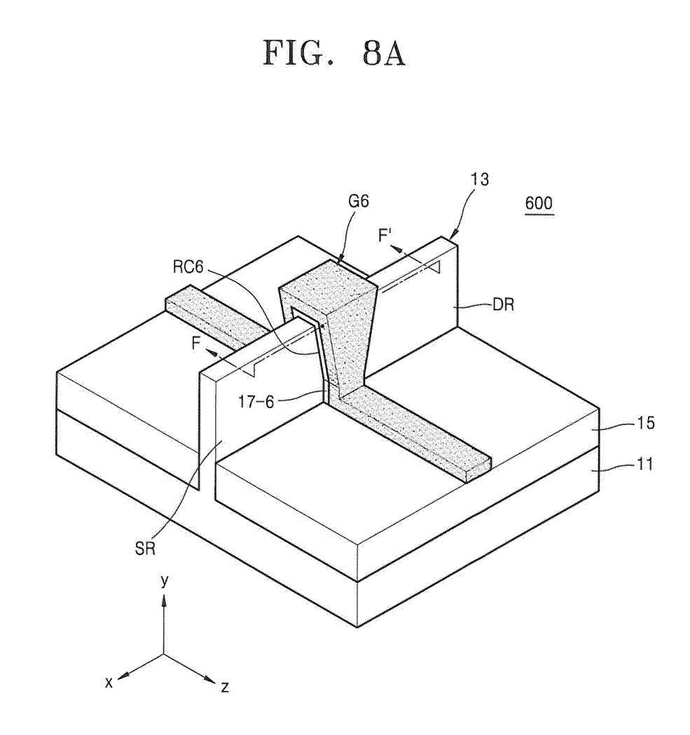

FIG. 10 is a perspective view of a semiconductor device 800 according to exemplary embodiments of the inventive concept. The semiconductor device 800 is similar to the semiconductor device 100 shown in FIGS. 1A to 1C except for structures of a semiconductor substrate 21 and a fin-type structure 23.

Referring to FIG. 10, the semiconductor device 800 may include a semiconductor substrate 21, a buried layer 25 formed on the semiconductor substrate 11, a fin-type structure 23 protruding upward from the buried layer 25, and a gate G1 that covers a top surface 23t and two side surfaces 23s of the fin-type structure 23 and extends onto a top surface of the buried layer 25. A width of a portion of the gate G1 that covers the side surfaces of the fin-type structure 23 may be reduced from an upper portion of the gate G1 toward a lower portion thereof.

FIGS. 1A to 10 illustrate examples that various gates G1, G1′, G2, G3, G4, G5, G6, and G7 are formed in the semiconductor devices 100, 150, 200, 300, 400, 500, 600, 700, and 800, but the inventive concept is not limited thereto. For example, the inventive concept may be applied to a semiconductor device including a gate structure having various shapes, which includes a range of which a width is reduced from an upper portion of a fin-type structure toward a lower portion thereof on side surfaces of the fin-type structure for at least some portion of the fin structure. Also, the gate structure may be variously selected according to purposes. The gate structure may be configured to solve a problem in which a source-drain voltage difference is reduced from the upper portion of the fin-type structure toward the lower portion thereof. Even if the source-drain voltage difference is reduced from the upper portion of the fin-type structure to the lower portion thereof, a sufficient channel current may be ensured. As a result, an efficient semiconductor device, which may enable high-speed operations and reduce power consumption thereof, may be provided.

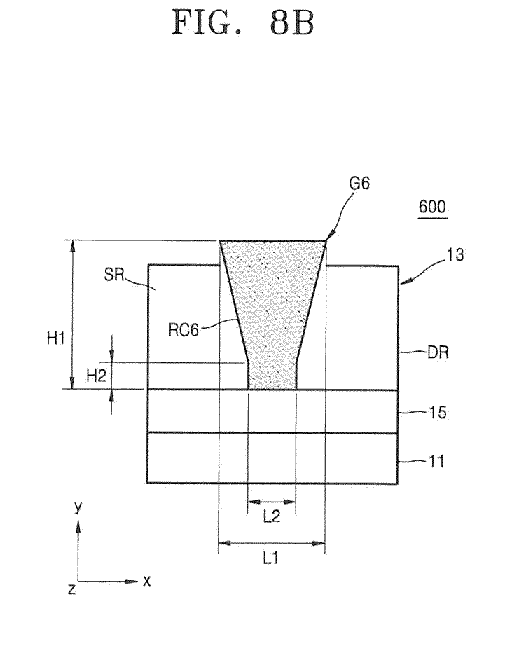

FIG. 11 is a perspective view of a semiconductor device 900 according to exemplary embodiments of the inventive concept. The semiconductor device 900 may include a plurality of semiconductor devices 100, each of which is as described with reference to FIGS. 1A to 1C.

Referring to FIG. 11, the semiconductor device 900 may include a semiconductor substrate 11, a plurality of fin-type structures 33a and 33b formed on the semiconductor substrate 11, an insulating layer 15 formed on the semiconductor substrate 11 to have a top surface that is at a lower level than the plurality of fin-type structures 33a and 33b, and a plurality of gates Ga and Gb that extend on the insulating layer 15 and cover top surfaces and side surfaces of the respective fin-type structures 33a and 33b to intersect the respective fin-type structures 33a and 33b. In this case, at least one of the gates Ga and Gb may include a range in which the width of the at least one of the gates Ga and Gb is reduced toward a lower portion of the corresponding one of the fin-type structures 33a and 33b on ₜhe side surfaces of the corresponding one of the fin-type structures 33a and 33b.

The plurality of fin-type structures 33a and 33b may extend in one direction to be parallel to one another. At least one of the plurality of gates Ga and Gb may be formed to extend in a perpendicular direction (e.g. the z-direction), so as to intersect with the plurality of fin-type structures 33a and 33b.

FIG. 11 illustrates a case in which the semiconductor device 900 includes a plurality of semiconductor devices, each of which is the same as the semiconductor device 100 described with reference to FIGS. 1A to 1C, but the inventive concept is not limited thereto. In some embodiments, the semiconductor device 900 may include a plurality of semiconductor devices, each of which is selected from among the semiconductor devices 150, 200, 300, 400, 500, 600, 700, and 800 described with reference to FIGS. 1D and 2A to 10. Also, each of the semiconductor devices 100, 150, 200, 300, 400, 500, 600, 700, and 800 may be variously disposed in the semiconductor device 900.

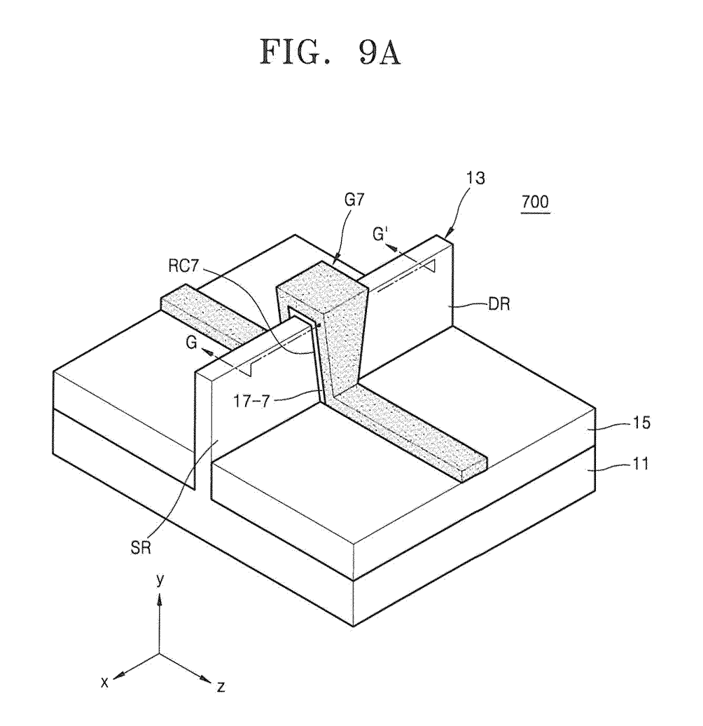

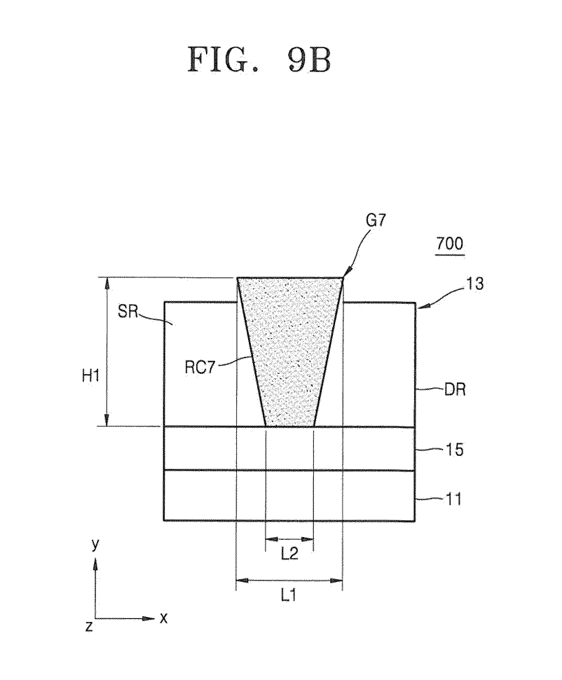

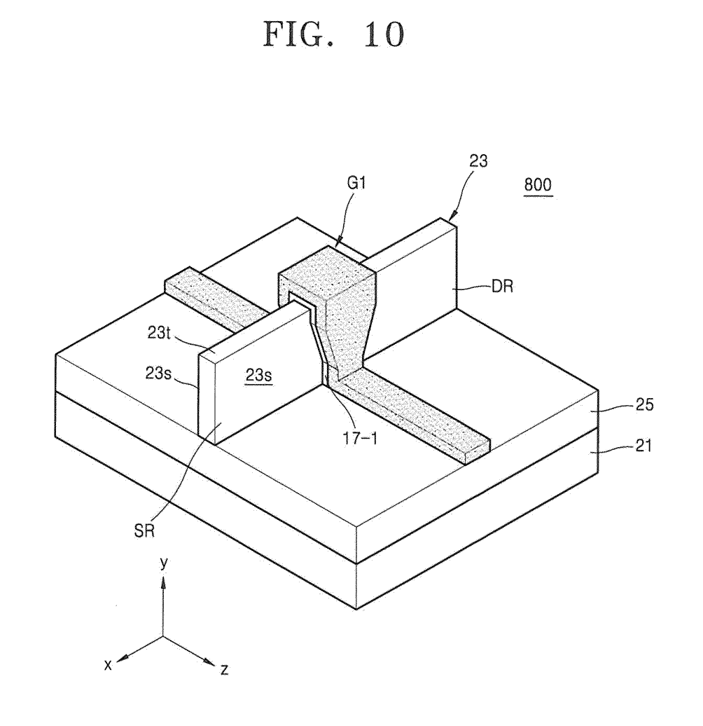

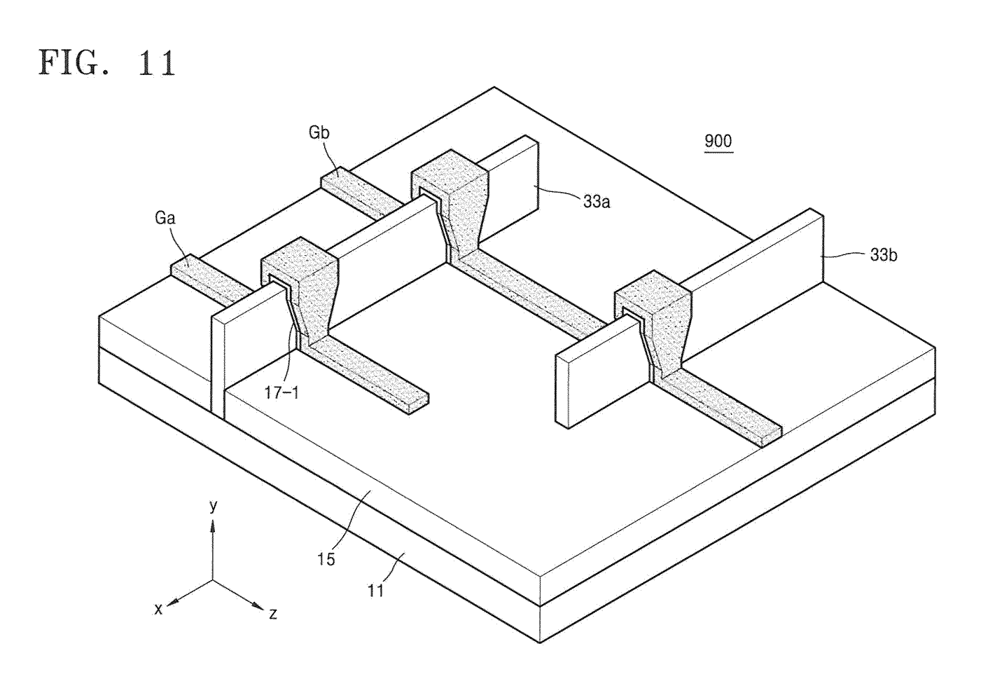

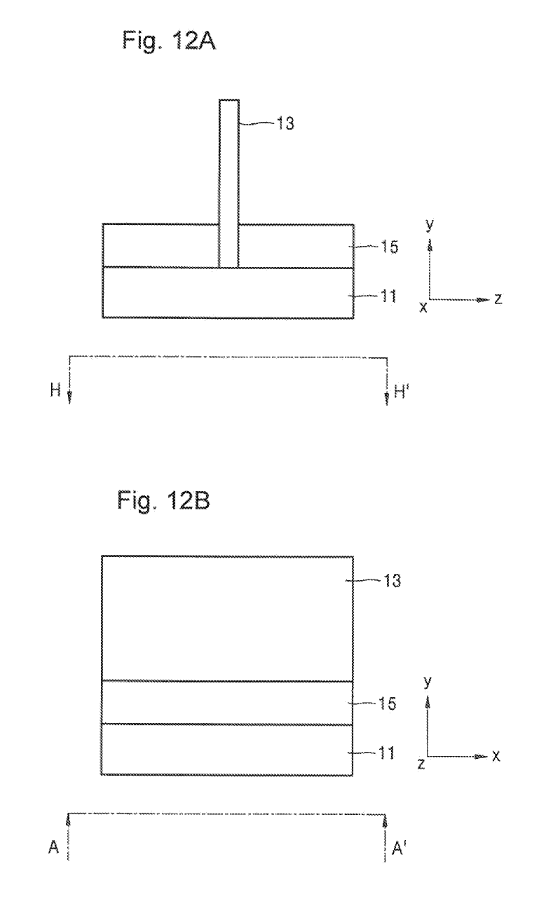

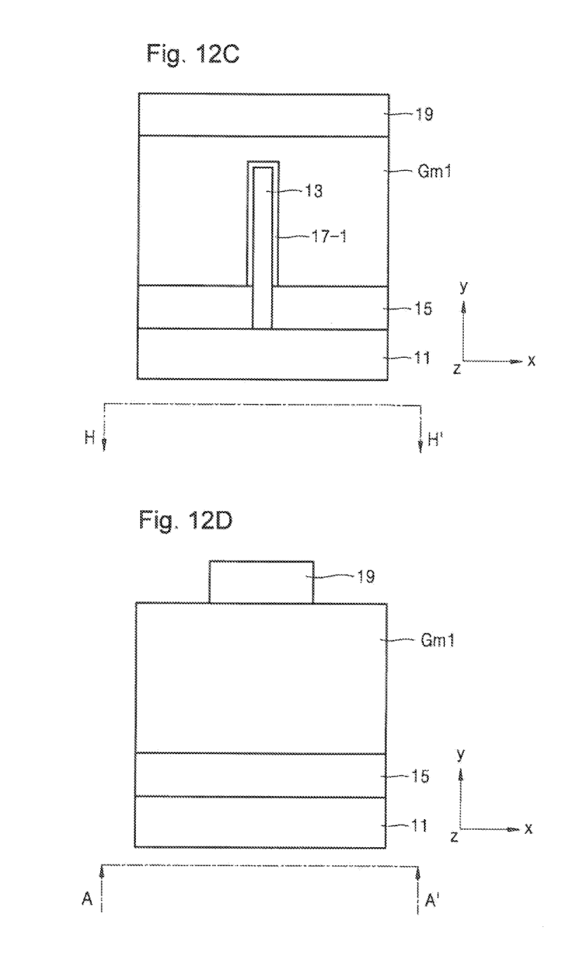

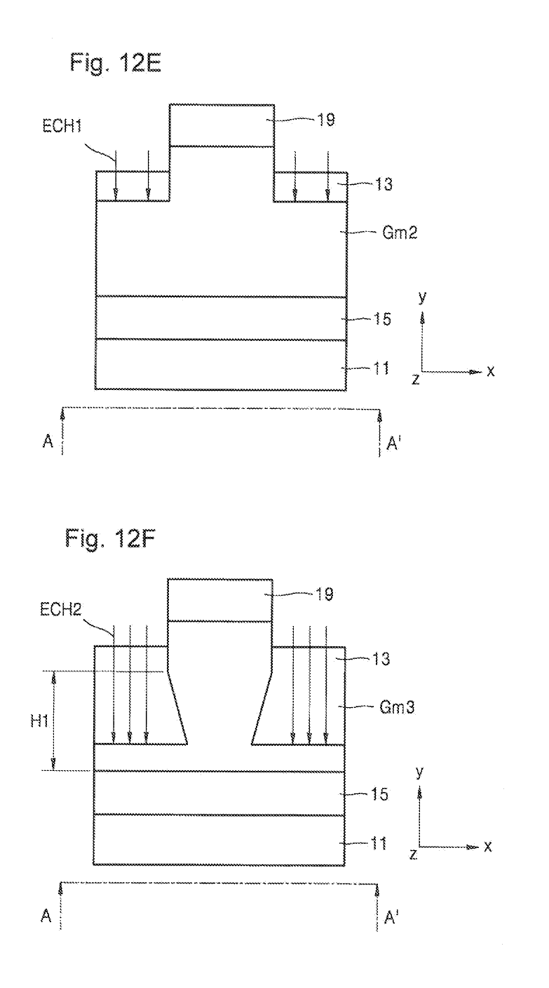

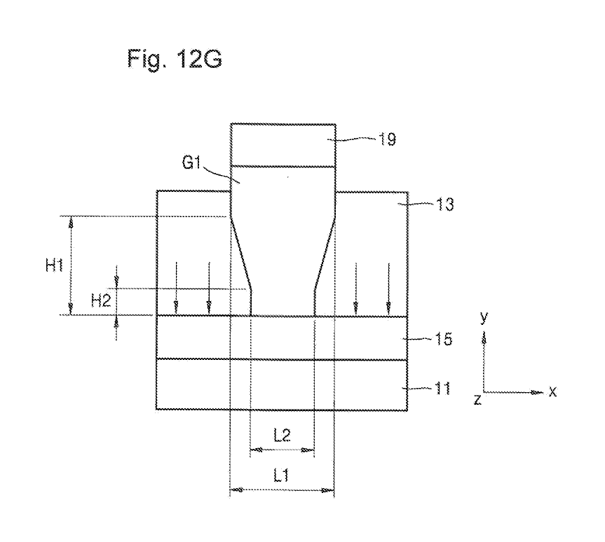

FIGS. 12A to 12G are front views illustrating a method of fabricating a semiconductor device 100, according to exemplary embodiments of the inventive concept. 12A and 12C are cross-sectional views taken along a line H-H′ of FIG. 1A, and FIGS. 12B and 12D are cross-sectional views taken along a line A-A′ of FIG. 1A.

Referring to FIGS. 12A and 12B, a photolithography process and an etching process may be performed to form a fin-type structure 13 on a semiconductor substrate 11. The fin-type structure 13 may extend in one direction (x-direction). After the fin-type structure 13 is formed, an insulating layer 15 may be formed on the semiconductor substrate 11, and a front surface of the insulating layer 15 may be etched to a predetermined thickness such that the fin-type structure 13 has an appropriate height.

Referring to FIGS. 12C and 12D, a gate dielectric layer 17-1 may be formed to cover the exposed fin-type structure 13. Thereafter, a gate material layer Gm1 may be formed to cover the semiconductor substrate 11 and the fin-type structure 13 covered with the gate dielectric layer 17-1. A hard mask pattern 19 may be formed on the gate material layer Gm1 to form the gate G1 of FIG. 1C. Thus, the hard mask pattern 19 may extend in a z-direction.

Referring to FIG. 12E, the gate material layer Sm1 of FIGS. 12C and 12D may be etched to a first level H1 by using the hard mask pattern 19 under first etch conditions ECH1. Thus, a gate material layer Gm2, including an upper portion of the gate G1 of FIG. 1, which may have a constant width that is similar to the width of the hard mask pattern 19, may be left.

The first etch conditions ECH1 may include all parameters, such as an etch gas, supplied power, pressure, and temperature, which may be factors that determine an etch rate of the gate material layer Gm2.

Referring to FIG. 12F, the gate material layer Gm2 of FIG. 12E may be etched to a second level H2 under second etch conditions ECH2, which are different from the first etch conditions ECH1 of FIG. 12E. In this case, at least one of the parameters, such as an etch gas, supplied power, pressure, and temperature, which may be factors that determine an etch rate, may be controlled such that an etch rate is higher under the second etch conditions ECH2 than under the first etch conditions ECH1. Thus, the gate material layer Gm2 may be etched to a large extent such that the width of the gate material layer Gm3 obtained between the first level H1 and the second level H2 is less than the width of the hard mask pattern 19 and a first width L1 of the gate material layer Gm3 obtained at the first level H1. As a result, the gate material layer Gm3 may have a second width L2 at the second level H2.

Referring to FIG. 12G, the gate material layer Gm3 of FIG. 12F may be completely etched under third etch conditions ECH3, which are different from the second etch conditions ECH2. In this case, at least one of the parameters, such as an etch gas, supplied power, pressure, and temperature, which may be factors that determine an etch rate, may be controlled such that an etch rate is lower under the third etch conditions ECH3 than under the second etch conditions ECH2. Thus, the gate G1 formed in the semiconductor device 100 shown in FIGS. 1A to 1C may be obtained.

Although not shown, spacers including an insulating material may be formed on sidewalls of the gate G1. In other embodiments, the spacers may be formed to cover the gate G1 and cover the fin-type structure 13.

The method shown in FIGS. 12A to 12G may be used to fabricate the semiconductor devices 150, 200, 300, 400, 500, 600, and 700 shown in FIGS. 1D and 4A to 9B by appropriately modifying etching conditions.

FIG. 13 is a diagram of a system 1000 including a semiconductor device according to an exemplary embodiment of the inventive concept.

Referring to FIG. 13, the system 1000 may include a controller 1010, an input/output (I/O) device 1020, a memory device 1030, and an interface 1040. The system 1000 may be a mobile system or a system configured to transmit or receive information. In some embodiments, the mobile system may be a personal digital assistant (PDA), a portable computer, a web tablet, a wireless phone, a mobile phone, a digital music player, or a memory card.

The controller 1010 may be configured to control an execution program in the system 1000. The controller 1010 may include a microprocessor (MP), a digital signal processor (DSP), a microcontroller (MC), or a device similar thereto. The controller 1010 may include a semiconductor device including a FinFET according to an exemplary embodiment of the inventive concept. For example, the controller 1010 may include at least one of the semiconductor devices 100, 150, 200, 300, 400,500, 600, 700, 800, and 900 shown in FIGS. 1A to 11.

The I/O device 1020 may be used to input or output data to or from the system 1000. The system 1000 may be connected to an external device (e.g., a personal computer (PC) or a network) using the I/O device 1020, and exchange data with the external device. The I/O device 1020 may be, for example, a keypad, a keyboard, or a display device,

The memory device 1030 may store codes and/or data for operations of the controller 1010, or store data processed by the controller 1010. The memory device 1030 may include a semiconductor device including a FinFET according to an exemplary embodiment of the inventive concept. For example, the memory device 1030 may include at least one of the semiconductor devices 100, 150, 200, 300, 400,500, 600, 700, 800, and 900 shown in FIGS. 1A to 11.

The interface 1040 may be a data transmission path between the system 1000 and another external device. The controller 1010, the I/O device 1020, the memory device 1030, and the interface 1040 may communicate with one another through a bus 1050. The system 1000 may be used in a mobile phone, an MPEG-1 audio layer 3 (MP3) player, a navigation system, a portable multimedia player (PMP), a solid-state disk (SSD), or household appliances.

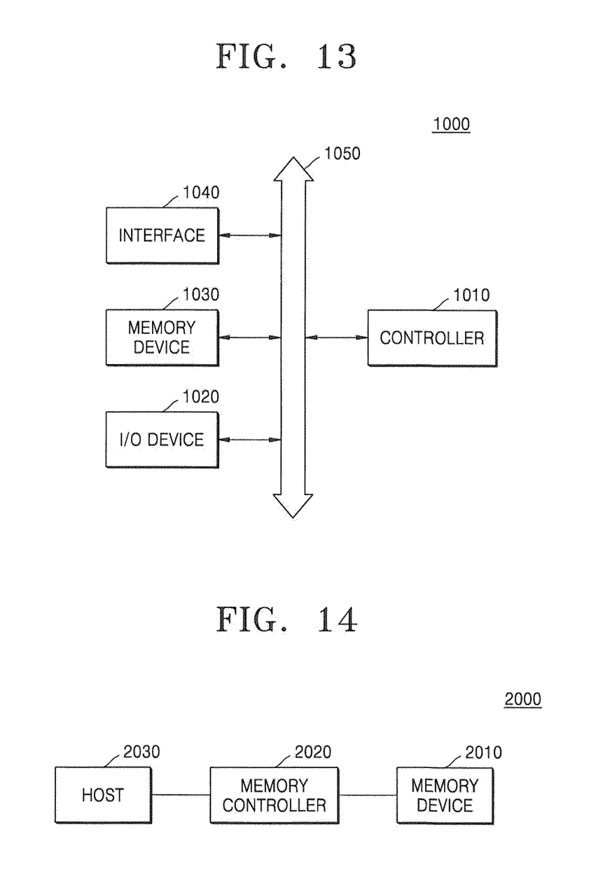

FIG. 14 is a diagram of a memory card 2000 including a semiconductor device according to an exemplary embodiment of the inventive concept.

Referring to FIG. 14, the memory card 2000 may include a memory device 2010 and a memory controller 2020.

The memory device 2010 may store data. In some embodiments, the memory device 2010 may be a non-volatile device capable of retaining stored data even if power supply is interrupted. The memory device 2010 may include a semiconductor device including a FinFET according to an exemplary embodiment of the inventive concept. For example, the memory device 1030 may include at least one of the semiconductor devices 100, 150, 200, 300, 400,500, 600, 700, 800, and 900 shown in FIGS. 1A to 11.

The memory controller 2020 may read data stored in the memory device 2010 or store data in the memory device 2010 in response to read/write requests from a host 2030. The memory controller 2020 may include a semiconductor device including a FinFET according to an exemplary embodiment of the inventive concept. For example, the memory device 1030 may include at least one of the semiconductor devices 100, 150, 200, 300, 400,500, 600, 700, 800, and 900 shown in FIGS. 1A to 11.

While the inventive concept has been particularly shown and described with reference to exemplary embodiments thereof, it will be understood that various changes in form and details may be made therein without departing from the spirit and scope of the following claims.

What is claimed is:

1. A semiconductor device comprising:
a semiconductor substrate having an upper surface;
a fin-type structure on the semiconductor substrate, the fin-type structure having a top surface opposite the substrate and two opposing side surfaces; and
a gate on a portion of the top surface and portions of the two side surfaces of the fin-type structure;
wherein the gate has a first width at a first level from the upper surface of the substrate and a second width at a second level from the upper surface of the substrate,
wherein the second level is lower than the first level,
wherein the first width is greater than the second width, and
wherein a width of the gate is reduced from the first width to the second width between the first level and the second level.

2. The device of claim 1, wherein the width of the gate is reduced with a constant rate of change from the first width to the second width between the first level and the second level.

3. The device of claim 1, wherein the width of the gate is reduced with at least two rates of change from the first width to the second width between the first level and the second level.

4. The device of claim 1, wherein the width of the gate is reduced at a continuously varying rate of change from the first width to the second width between the first level and the second level.

5. The device of claim 1, wherein the first level is at substantially the same level as a top surface of the gate.

6. The device of claim 1, wherein the first level is at a lower level than a top surface of the gate.

7. The device of claim 1, further comprising an insulating layer formed on the semiconductor substrate to have a top surface that is at a lower level than a top surface of the fin-type structure, wherein the second level is at substantially the same level as the top surface of the insulating layer.

8. The device of claim 1, farther comprising an insulating layer formed on the semiconductor substrate to have a top surface that is at a lower level than a top surface of the fin-type structure, wherein the second level is at an upper level than the top surface of the insulating layer.

9. The device of claim 1, wherein a third width of the gate at a third level that is lower than the second level is equal to or larger than the second width.

10. The device of claim 1, wherein a third width of the gate at a third level that is lower than the first level is equal to or smaller than the first width.

11. The device of claim 1, wherein on side surfaces of the fin-type structure, a source region and a drain region are formed on the fin-type structure on two sides of the gate, wherein a first resistance between the source region and the drain region on the two sides of the gate at the first level is greater than a second resistance between the source region and the drain region on the two sides of the gate at the second level.

12. The device of claim 1, wherein the fin-type structure protrudes from the substrate, and the insulating layer defines the fin-type structure.

13. The device of claim 1, wherein the fin-type structure is formed on the insulating layer.

14. A semiconductor device comprising:
a semiconductor substrate;
a fin-type structure on the semiconductor substrate;
an insulating layer formed on the semiconductor substrate to have a top surface that is at lower level than a top surface of the fin-type structure; and
a gate on a portion of a top surface of the fin-type structure and portions of side surfaces of the fin-type structure,
wherein a width of the gate is reduced from a first width at an upper portion of the fin-type structure to a second width at a lower portion of the fin-type structure.

15. The device of claim 14, wherein, in a range, the gate includes a first side and a second side that extend from an upper portion of the fin-type structure toward a lower portion thereof, the first side of the gate extends in a first direction, and the second side of the gate extends in a second direction that is inclined at a different angle from the first direction with respect to a direction vertical to the insulating layer.

16. A semiconductor device, comprising:
a semiconductor substrate having an upper surface;
a fin on the semiconductor substrate, the fin having an upper portion distal from the substrate and a lower portion proximate the substrate, and including a source region and a drain region in opposite ends of the fin and a channel region between the source region and the drain region;
a gate on the channel region and extending down a side of the fin from a top of the fin towards a bottom of the fin between the source region and the drain region;
a source contact on an upper surface of the fin in the source region; and
a drain contact on an upper surface of the fin in the drain region,
wherein the gate has a first width at the upper portion of the fin and a second width at the lower portion of the fin, the first width being greater than the second width.

17. The device of claim 16, wherein the width of the gate has a constant rate of change from the first width to the second width.

18. The device of claim 16, wherein the width of the gate is reduced with at least two rates of change from the first width to the second width.

19. The device of claim 16, wherein the width of the gate is reduced at a continuously varying rate of change from the first width to the second width.

20. The device of claim 16, wherein the gate has a third width at a portion of the fin beneath the second width, the third width being greater than the second width.
